(19) United States
(12) Patent Application Publication
(10) Pub. No.: US 2025/0183175 A1
(43) Pub. Date: Jun. 5, 2025

(54) SEMICONDUCTOR DEVICE WITH METAL STRUCTURE PASSIVATION

(71) Applicant: Infineon Technologies AG, Neubiberg (DE)

(72) Inventors: Roman Roth, Sattendorf (AT); Jean-Charles Cigal, Dresden (DE); Markus Kahn, Rangersdorf (AT); Angelika Koprowski, Klagenfurt (AT)

(21) Appl. No.: 18/945,767

(22) Filed: Nov. 13, 2024

(30) Foreign Application Priority Data
Nov. 30, 2023 (DE) 102023133538.3

(51) Int. Cl. H01L 23/532; H01L 21/768; H01L 29/66; H01L 29/78

(52) U.S. Cl. CPC H01L 23/53233; H01L 21/76834; H01L 21/76856; H01L 23/53238; H10D 30/0297; H10D 30/665

(57) ABSTRACT

A semiconductor device includes a semiconductor substrate. A metal structure is disposed over the semiconductor substrate. A metal of the metal structure is Cu or a Cu-based alloy. A passivation layer is disposed over the metal structure. The passivation layer includes a first layer including CuSiN, and a second layer including Si, N and H. In atomic numbers, a ratio of Si to N is equal to or greater than 3.3/4. A method of manufacturing the semiconductor device is also described.

### TECHNICAL FIELD

This disclosure relates generally to the field of power semiconductor devices, and in particular to a semiconductor device having a metal structure passivation.

### BACKGROUND

Semiconductor devices in general and power semiconductor devices in particular are often sensitive to environmental influences such as humidity and temperature fluctuations. These influences can lead to changes in material properties and electrical characteristics, e.g. a deviation in the breakdown voltage of the device. In addition, the lifetime of the semiconductor device can be shortened.

Passivation layers on metal structures are used to improve the resistance of the device to environmental influences. However, the integration of a passivation layer on metal can be difficult with regard to the required high adhesion and compliance with the electrical requirements, especially the suitability for chip edge termination.

### SUMMARY

According to an aspect of the disclosure, a semiconductor device includes a semiconductor substrate. A metal structure is disposed over the semiconductor substrate, wherein a metal of the metal structure is Cu or a Cu-based alloy. A passivation layer is disposed over the metal structure, wherein the passivation layer includes a first layer comprising CuSiN, and a second layer comprising Si, N and H, wherein, in atomic numbers, a ratio of Si to N is equal to or greater than 3.3/4.

According to another aspect of the disclosure, a method of manufacturing a semiconductor device comprises providing a semiconductor substrate; forming a metal structure over the semiconductor substrate, wherein a metal of the metal structure is Cu or a Cu-based alloy; and forming a passivation layer over the metal structure, the forming of the passivation layer comprising forming a first layer comprising CuSiN, and forming a second layer comprising Si, N and H, wherein, in atomic numbers, a ratio of Si to N is equal to or greater than 3.3/4.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross-sectional representation of an example of a semiconductor substrate, a metal structure disposed on the substrate and a passivation layer disposed on the metal structure of a semiconductor device.

FIG. 2 is a schematic plan view of an example of a semiconductor device illustrating an active region, a chip edge and an edge termination region in between.

FIG. 3 is a schematic cross-sectional partial view of an example of a semiconductor device illustrating an active region, a chip edge and an edge termination region in between.

FIG. 4 is a schematic cross-sectional partial view of an example of a semiconductor device including a power pad and other metal structures such as, e.g., a signal routing structure or a field plate of an exemplary semiconductor device.

FIG. 5 is a flowchart illustrating exemplary stages of a method of manufacturing a semiconductor device having a metal structure and a passivation layer disposed on the metal structure.

FIG. 6 is a flowchart illustrating exemplary stages of a process of forming a passivation layer in accordance with stage S3 of FIG. 5.

### DETAILED DESCRIPTION

It is to be understood that the features of the various exemplary embodiments and examples described herein may be combined with each other, unless specifically noted otherwise.

As used in this specification, the terms “deposited”, “covered by”, “connected” and/or “electrically connected” are not meant to mean that the elements or layers must directly be contacted together; intervening elements or layers may be provided between the “deposited”, “covered by”, “connected”, and/or “electrically connected” elements, respectively. However, in accordance with the disclosure, the above-mentioned terms may, optionally, also have the specific meaning that the elements or layers are directly contacted together, i.e. that no intervening elements or layers are provided between the “deposited”, “covered by”, “connected”, and/or “electrically connected” elements, respectively.

Further, the word “over” used with regard to a part, element or material layer formed or located or arranged “over” a surface may be used herein to mean that the part, element or material layer be located (e.g. placed, formed, arranged, deposited, etc.) “directly on”, e.g. in direct contact with, the implied surface. The word “over” used with regard to a part, element or material layer formed or located or arranged “over” a surface may either be used herein to mean that the part, element or material layer be located (e.g. placed, formed, arranged, deposited, etc.) “indirectly on” the implied surface with one or more additional parts, elements or layers being arranged between the implied surface and the part, element or material layer.

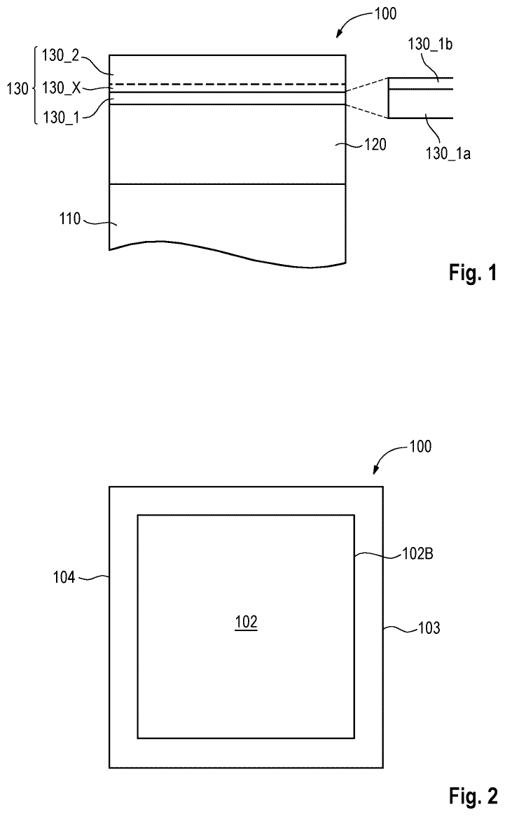

Referring to FIG. 1, an example of a semiconductor device 100 includes a semiconductor substrate 110. A metal structure 120 is disposed over the semiconductor substrate 110. A metal of or contained in the metal structure 120 is Cu or a Cu-based alloy.

A passivation layer 130 is disposed over the metal structure 120. The passivation layer 130 includes a first layer 130_1 and a second layer 130_2. The first layer 130_1 comprises or is of CuSiN. The second layer 130_2 comprises or is composed of Si, N and H. In atomic numbers a ratio of Si to N is equal to or greater than 3.3/4.

As will be described in more detail further below, the passivation layer 130 may have various functions. First, the passivation layer 130 may provide high suitability for passivation, e.g., for moisture protection of underlying structures. Second, the passivation layer 130 may provide good adhesion to underlying structures such as, e.g., the metal structure 120 and/or to overlying structures such as, e.g., an imide layer (not shown in FIG. 1). Third, the passivation layer 130 may, e.g., be used for electrical contacting the chip edge. In power semiconductor devices the chip edge may be at a high voltage. The passivation layer 130 may, e.g., provide an electrical function to balance the voltage drop between the chip edge and the active region so that it does not negatively affect the electrical properties of the device, for example. For this purpose the passivation layer 130 may have a specific electrical conductivity which is not too large but also not too small. Moreover, the passivation layer 130 may form a charge shielding layer to protect the chip edge termination from outer charges.

In the semiconductor device 100 the second layer 130_2 including Si, N and H in the composition described above may meet the requirements with regard to protection against environmental impact, adhesion and electrical conductivity. However, as will be described in more detail further below, the second layer 130_2 cannot be deposited in a controlled way directly on the metal structure 120.

The first layer 130_1 includes CuSiN to suppress CuSi formation and thus enables controlled deposition of the second layer 130_2. In other words, by combining the first layer 130_1 and the second layer 130_2, a metal structure 120 including or being of Cu can be effectively passivated by a passivation layer 130, which may fulfill all requirements and, in particular, the electrical and protection requirements for chip edge termination, for example.

For example, the first layer 130_1 may comprise or consist of two layers, namely an (optional) CuSi layer 130_1a and a CuSiN layer 130_1b disposed above the CuSi layer 130_1a and representing, for example, the surface of the first layer 130_1.

Optionally, at least one intermediate layer 130_x may be disposed between the first layer 130_1 and the second layer 130_2. The intermediate layer 130_x may comprise or be of aluminum oxide, e.g. Al₂O₃. The (optional) intermediate layer 130_x may be deposited by ALD (atomic layer deposition). The intermediate layer 130_x may have a small thickness such as, e.g., below one or a few nm.

The metal structure 120 may, e.g., be a chip pad or any other metal structure used in the semiconductor device 100. For example, the metal structure 120 may be a gate runner or field plate of the semiconductor device 100.

Depending on whether the semiconductor device 100 is a power device or not and depending on the type of the metal structure 120, the metal structure 120 may, e.g., have a thickness between 1 and 30 μm, in particular 4 and 14 μm. For example, the first layer 130_1 may have a thickness between 1 and 115 nm (depending on whether and, if so, how thick a CuSi layer 130_1a is included in the first layer 130_1, see the following more detailed description). The thickness of the first layer 130_1 can be small, because the first layer 130_1 may not provide volume-dependent functionality. Rather, the first layer 130_1 may provide a nitrided copper silicide surface that prevents an excessive CuSi growth when forming the second layer 130_2 of the passivation layer stack 130.

The second layer 130_2 may have a layer thickness between 40 and 500 nm. In particular, a thickness between 200 nm, 250 nm or 300 nm as a lower limit and 500 nm or 400 nm as un upper limit may be suitable. The second layer 130_2 may provide the moisture protective and/or electrical characteristics of the passivation layer 130, i.e. may provide volume-dependent functionality.

The semiconductor substrate 110 may, e.g., be a Si substrate, a Si-on-isolator (SOI) substrate, a GaN substrate, a SiC substrate, a GaAs substrate, or a substrate of any other IV-IV, III-V or II-VI semiconductor material, such as, e.g., SiGe, GaAs, AlGaN, InGaAs, InAlAs, etc. The semiconductor substrate 110 may be a semiconductor body or a semiconductor chip formed of one or a plurality of the above materials, for example.

The semiconductor device 100 may, e.g., be a vertical device or a horizontal device. In a vertical device, the main direction of a load current is in a vertical direction, while in a horizontal (or lateral) device, the main direction of a load current is in horizontal (lateral) direction.

The semiconductor device 100 (e.g. a semiconductor chip) may, for example, be configured as an IGBT (Insulated Gate Bipolar Transistor), a FET (Field Effect Transistor), in particular a MOSFET (Metal Oxide Semiconductor FET) such as, e.g., a P-FET (P-channel FET), an N-FET (N-channel FET), an AFET (Array-FET), a JFET (Junction gate FET), a planar gate transistor, a field plate trench transistor, or a SJ (super junction) transistor. Further, the semiconductor device 100 may, for example, be configured as a diode.

FIG. 2 illustrates a plan view of a semiconductor device 100 illustrating functionality regions of the device 100. In the example shown, the semiconductor device 100 may be a power and/or high voltage device 100.

The semiconductor device 100 may include an active region 102. The active region 102 may be confined by a border 102B where the active region 102 transitions into an edge termination region 103. The edge termination region 103 may surround the active region 102 and terminate at the chip edge 104.

The purpose of the active region 102 is primarily to ensure load current conduction. The edge termination region 103 may be configured to reliably terminate the active region 102. More specifically, the edge termination region 103 is typically not used for load current conduction purposes, but to safely terminate the active region 102 and guarantee robust blocking characteristics of the semiconductor device 100.

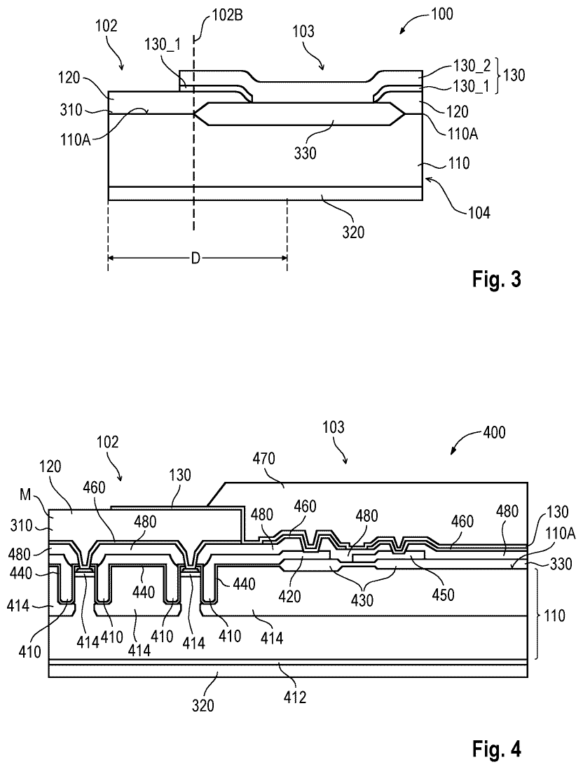

FIG. 3 illustrates a cross-sectional view of a portion of an exemplary semiconductor device 100. In the example shown, the semiconductor device 100 is a vertical device.

The semiconductor device 100 may include the semiconductor substrate 110 coupled to a first load terminal 310 and a second load terminal 320. Within the active region 102 a load current may be conducted between the first load terminal 310 and the second load terminal 320. For example, the semiconductor substrate 110 may include a drift zone for conduction of the load current. In the example shown, the load current path is in a vertical direction.

The first load terminal 310 may, e.g., correspond to the metal structure 120 as described in connection with FIG. 1. That is, the metal structure 120 may be at least partially overlaid by the passivation layer 130. For example, the first load terminal 310 may be a source (or emitter) terminal of the semiconductor (transistor) device 100. The second load terminal 320 may, e.g., be a drain (or collector) terminal of such semiconductor device 100.

Within the edge termination region 103, the semiconductor device 100 may include an edge termination structure 330. The edge termination structure 330 may, e.g., be arranged partly or completely within the semiconductor substrate 110.

At an upper surface 110A of the semiconductor substrate 110 the electrical potentials of both load terminals 310, 320 may be present. For example, at the chip edge 104 the electrical potential of the second load terminal 320 may be present along the full vertical extension of the semiconductor substrate 110. If, e.g., a metal structure 120 is arranged adjacent to the chip edge 104 (as shown in the example of FIG. 3), the metal structure at the chip edge 104 is at the same electrical potential as the second load terminal 320. This potential may, e.g., be a high voltage potential of equal to or greater than 0.2 kV, 0.5 kV, 0.7 kV, 1 kV, 1.5 kV, 2 kV, 3 kV or 5 kV or 7 kV.

On the other hand, the electrical potential at the metal structure 120 forming the first load terminal 310 may, e.g., be substantial lower, e.g. about 0 V or equal to or smaller than 10 V, 20 V or 30 V. Hence, for a high voltage or power semiconductor device 100, a voltage applied between the first load terminal 310 and the second load terminal 320 may have substantially the same values as mentioned above for the potential of the second load terminal 320. The voltage applied between the first load terminal 310 and the second load terminal 320 may, for example, be referred to as “emitter-collector voltage” or “source-drain voltage”.

The edge termination region 103 may be configured to balance between these electrical potentials, e.g. to prevent an electrical breakthrough. Along the edge termination region 103, or, respectively, along the (optional) edge termination structure 330, the electrical potential may transition from the potential of the first load terminal 310 to the potential of the second load terminal 320 (present at the chip edge 104). For example, on a first side of the edge termination region 103, or, respectively, of the (optional) edge termination structure 330, the potential may be equal or similar to the potential of the first load terminal 310, and on a second side of the edge termination region 103, or, respectively, of the (optional) edge termination structure 330, the potential may be equal or similar to the potential of the second load terminal 320. The first side of the edge termination region 103, or, respectively, of the edge termination structure 330, is closer to the active region 102, while the second side of the edge termination region 103, or, respectively, of the edge termination structure 330, is closer to the chip edge 104.

The passivation layer 130 may, e.g., be arranged within a part of the active region 102 and/or within a part or over the full extension of the edge termination region 103. For example, the second layer 130_2 of the passivation layer 130 may extend as a continuous layer from the chip edge 104 into the active region 102. The passivation layer 130 extends at least partly over the metal structure 120. The second layer 130_2 may extend, e.g., partly over a non-metal structure such as, e.g., the edge termination structure 330. The first layer 130_1 does not extend over non-metal structures. In other words, the passivation layer 130 may comprise the second layer 130_2 but not the first layer 130_1 in regions vertically over non-metal structures. As illustrated by way of example in FIG. 3, the passivation layer 130 may be arranged over the metal structure 120 within the active region 102 and/or may be arranged over the metal structure 120 within the edge termination region 103.

The edge termination structure 330 may be implemented in various different ways. For example, the edge termination structure 330 may include or embody a VLD (variation of lateral doping) zone. A VLD zone may comprise a semiconductor region with laterally decreasing dopant concentration towards the chip edge 104. Alternatively or in addition, the edge termination structure 330 may include or be of an insulating layer such as, e.g., an oxide layer. For example, the edge termination structure 330 may include or be formed of a LOCOS (locally oxidized silicon) layer which may, optionally, overlay a VLD zone located below in the semiconductor substrate 110. In this case, the insulating layer of the edge termination structure 330 may electrically insulate the passivation layer 130 from the semiconductor substrate 110 or, in particular, from a VLD zone formed in the semiconductor substrate 110. The insulating layer may extend along the full extension between the metal structure 120 in the active region 102 and, if existing, the metal structure 120 in the edge termination region 103 or the chip edge 104.

As the passivation layer 130 may continuously extend from the metal structure 120 of the active region 102 to the chip edge 104 (or the metal structure 120 in proximity of or at the chip edge 104), the passivation layer 130 may provide a homogenous high-ohmic conduction path between the first load terminal 310 and the chip edge 104 (and/or the metal structure 120 in proximity of or at the chip edge 104). For example, the passivation layer 130 may have a conductivity of equal to or greater than 1×10⁻⁴ S or 2×10⁻⁴ S and/or equal to or less than 5×10⁻³ S within a temperature range from 273 K to 473 K. Such high-ohmic conduction path is suitable for balancing the electrical potentials between the active region 102 and the chip edge 104.

The electrical characteristic of the passivation layer 130 is caused by the second layer 130_2. The second layer 130_2 comprises or consists of silicon nitride in a modified form that is not stoichiometric but has an increased silicon content.

More specifically, (stoichiometric) silicon nitride Si₃N₄ is an insulator. By increasing the silicon content in the second layer 130_2 such that, in atomic numbers, a ratio of Si to N is equal or greater than 3.3/4, the silicon nitride has an over-stoichiometric Si content. The passivation properties of the over-stoichiometric silicon nitride layer are (still) high. However, the integration of such over-stoichiometric silicon nitride layer on a metal structure including or being of Cu or a Cu-based alloy is difficult as the deposition process leads to thick CuSi layers and bad adhesion. The introduction of the first layer 130_1 including, e.g., a thin CuSiN layer under the over-stoichiometric silicon nitride layer (second layer 130_2) allows the integration of the second layer 130_2 on a Cu or Cu-based metal structure 120 with high adhesion of the passivation layer 130 on the metal structure 120.

For example, in at least a portion of the second layer 130_2 (or in the entire second layer 130_2), a ratio of silicon to nitride is equal to or greater than 3.3/4, in atomic numbers. In other examples the ratio of silicon to nitride in the second layer 130_2 may be equal to or greater than 3.6/4 or 3.8/4 or 1, in atomic numbers. For example, the number of silicon atoms may, e.g., be equal to or greater than 82.5% or 90% or 100% of a number of nitrogen atoms in the second layer 130_2. In some examples, the number of silicon atoms may, e.g., be greater than the number of nitrogen atoms in the second layer 130_2. In this case, the number of silicon atoms may, e.g., be equal to or greater than 110% or 120% or 130% or 140% or 150% of the number of nitrogen atoms in the second layer 130_2.

In some examples the second layer 130_2 may include 40 to 55 at % Si. In these or other examples the second layer 130_2 may include 30 to 45 at % N. The second layer 130_2 may further comprise H in, e.g., a concentration between 12 and 17 at %. Typical values, from which, however, considerable deviations are possible, are 48 at % Si, 36 at % N and 15 at % H.

FIG. 4 illustrates a cross-sectional partial view of an example of a semiconductor device 400. The portion of the semiconductor device 400 shown in FIG. 4 may correspond to the portion D of FIG. 3. In other words, FIG. 4 illustrates a transition from the active region 102 into the edge termination region 103. The chip edge 104 is not shown.

The first load terminal 310 (e.g. source pad) and a control terminal, e.g. a gate pad (not shown) may be located over the upper surface 110A of the semiconductor substrate 110.

The semiconductor substrate 110 may include a highly doped region 412 to contact the second load terminal 320 and a plurality of highly doped regions 414 adjacent to the upper surface 110A of the semiconductor substrate 110. The highly doped regions 414 may be located in the active region 102 and/or in the edge termination region 103.

In the active region 102 the semiconductor device 400 may include a plurality of gate contacts 410. The gate contacts 410 are exemplified in FIG. 4 as trench gates. For example, polysilicon gate contacts 410 may be used. Reference numeral 440 refers to a gate dielectric which insulates the gate contacts 410 from channel regions (not shown) of the (transistor) semiconductor device 400, for example. The channel regions may, e.g., be located along the gate contacts 410 in a vertical direction in the highly doped regions 414.

The gate contacts 410 may be connected to a gate runner 420, for example. The gate runner 420 may be insulated against the semiconductor substrate 110 by an insulating layer 430. The insulating layer 430 may, e.g., be an oxide layer. The insulating layer 430 may, e.g., be a LOCOS layer. The insulating layer 430 may, e.g., form a part of the edge termination structure 330.

The semiconductor device 400 may further include signal routing structures and/or field plates. Reference number 450 refers to such signal routing structure and/or field plate.

The semiconductor device 400 may include a metallization M. The metallization M may, e.g., comprise or be of Cu or a Cu-based alloy.

The semiconductor device 400 may, e.g., include a dielectric layer 480, which may also be referred to as an interlayer dielectric. The dielectric layer 480 may comprise or be of an organic or inorganic dielectric material. The dielectric layer 480 is an electrically insulating layer.

A barrier layer 460 may be applied over the dielectric layer 480. The barrier layer 460 may be structured to cover only a part of the surface of the dielectric layer 480. For example, in areas in which the metallization M (e.g. the metal structure 120 formed by structuring the metallization M) overlays (overlaps) the dielectric layer 480, the barrier layer 460 may completely cover the dielectric layer 480 to completely separate the dielectric layer 480 from the metallization M. In other areas, in which the dielectric layer 480 is not covered by the metallization M, the barrier layer 460 may either be omitted or may be structured to cover only parts of the dielectric layer 480, as shown in FIG. 4.

The barrier layer 460 may, e.g., comprise or be of a copper barrier material such as, e.g., TiW and/or TiN and/or W. Other types of barrier layers 460 may also be used.

The passivation layer 130 is formed over the metallization M and/or the dielectric layer 480, for example. It may also be formed over the barrier layer 460. As illustrated in FIG. 4 and mentioned before, the passivation layer 130 may be a continuous layer which extends from the metal structure 120 (e.g., source pad) across the edge termination region 103 to the chip edge 104 (not shown). In other words, the entire chip surface except contact regions of the metal structure 120 may be effectively sealed against environmental attack by the passivation layer 130.

Further, an organic insulating layer 470, e.g. an imide layer, may be arranged above the passivation layer 130. The organic insulating layer 470 may be a continuous layer which extends over the full edge termination region 103 to the chip edge 104 (not shown), for example. The organic insulating layer 470 may, e.g., extend over a portion of the metal structure 120 of the metallization M and over the entire extension of the passivation layer 130 outside the metal structure 120.

The organic insulating layer 470 may, e.g., include a polyimide (PI)-usually referred to as an imide- and/or polybenzoxazole (PBO) and/or epoxy and/or similar organic dielectrics.

The organic insulating layer 470 may have a thickness equal to or greater than 5 μm, 8 μm or 10 μm and equal to or less than 20 μm, 15 μm or 12 μm. For example, the thickness of the organic insulating layer 470 may be 11 μm.

The organic insulating layer 470 and/or the passivation layer 130 may, e.g., not reach into any region between the dielectric layer 480 and the metallization M, for example. Further, in some areas only the organic insulating layer 470 and the passivation layer 130 may be used to cover the dielectric layer 480, for example.

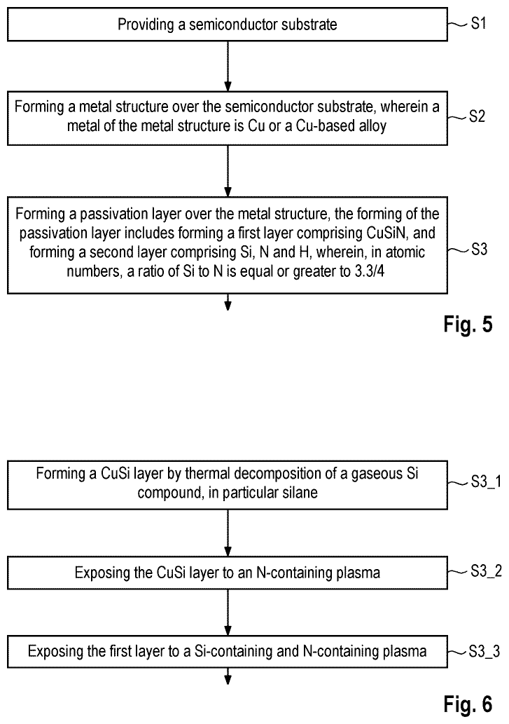

Referring to FIG. 5, exemplary stages of manufacturing a semiconductor device 100, 400 are described. At S1 a semiconductor substrate 110 is provided. The semiconductor substrate 110, e.g. a silicon body, may have undergone FEOL (front-end-of-line) processing to form an integrated circuit therein.

At S2 a metal structure 120 is formed over the semiconductor substrate 110. The metal structure 120 may comprise or be of Cu or a Cu-based alloy. As described above, before forming the metal structure 120, an insulating layer 430 and/or a barrier layer 460 may be formed.

The metal structure 120 may be formed by depositing a layer of the metal and structuring this layer by, e.g., Cu chemical wet etching. The layer may be formed by sputtering or electroplating of the metal (e.g., Cu or a Cu-based alloy). Optionally, a chemical mechanical polishing (CMP) process may follow.

At S3 the passivation layer 130 is formed over the metal structure 120. The forming of the passivation layer 130 includes forming a first layer 130_1 comprising CuSiN and forming a second layer 130_2 comprising Si, N and H.

Before forming the passivation layer 130 over the metal structure 120, a metal oxide (e.g., copper oxide) may be removed from the metal structure 120. For example, oxide removal may be carried out by a plasma treatment with a hydrogen precursor. The hydrogen precursor may, e.g., include or be NH₃ and/or H₂.

For example, a processing chamber (also referred to as a reaction chamber in the art), in which the semiconductor substrate 110 with the exposed metal structure 120 has been placed, is filled by a mixture of NH₃ and N₂. The oxide is removed by ignition of the hydrogen plasma.

The formation of the first layer 130_1 comprising CuSiN may start by setting a controlled low flow of a gaseous Si compound (e.g., silane), without plasma treatment at that time. Silane thermally reacts with copper to generate copper silicide (CuSi) on the surface of the metal structure 120. For example, a flow of 34 sccm of silane (e.g., monosilane SiH₄) and a flow of 4500 sccm of N₂ may be used.

All flow rates given here are exemplary. They may refer to 300 mm wafers, for example.

The silicidation of the metal surface may be followed by a plasma treatment. The plasma treatment is used for subsequent nitridation of the silicided metal surface. For example, a plasma treatment using NH₃ is carried out to generate a nitrided copper silicide (CuSiN) of the first layer 130_1.

The CusiN surface thus formed is stable and appears to be inert to many chemistries. In particular, the CusiN surface does not thermally react with silane. In other words, when the metal structure 120 coated with the first layer 130_1 (including the CuSiN-layer) is exposed to silane or another gaseous Si compound for silicon deposition, no silicon is thermally deposited on this surface.

Only a small part of the CuSi may be converted into CuSiN. For example, a CuSiN layer 130_1b of a thickness in a range between 1 and 15 nm, in particular 3 and 9 nm may be formed above the (optional) CuSi layer 130_1a. The CuSi layer 130_1a may have a thickness in a range between 0 nm and 200 nm, in particular between 0 and 100 nm.

That is, the first layer 130_1 may include two layers, namely the CuSi layer 130_1a and the CuSiN layer 130_1b. The (optional) CuSi layer 130_1a may have a thickness in a range between 0 nm and 200 nm or 0 nm and 150 nm or in a range of 50±50 nm or 50±40 nm or 50±30 nm or 50±20 nm or 50±10 nm or 50±0 nm. Above a thickness of 100 nm a deterioration of the bondability was noticed. It is to be noted that the term “CuSi” used here means CuSiₓ, since the stoichiometry (indicated by x) can be changed depending on the gas flow rates used.

Subsequently, the gas flow setting in the processing chamber is adjusted to prepare the formation of the second layer 130_2 of the passivation layer 130. This includes the flow rate setting of the gaseous Si compound (e.g. silane). A much higher flow rate (e.g., about 700 sccm) of the silicon precursor gas (i.e. the gaseous Si compound) is needed. Typically, setting the appropriate gas flows requires a few seconds for reaching stable flow conditions in the processing chamber, e.g. about 10 s. During this time the CusiN layer 130_1b prevents any thermal reaction of the Cu surface with the silicon precursor gas. Differently put, a CuSi will not grow during the gas flow setting process. Optionally, other processes (e.g., deposition of the intermediate layer 130_x) may be conducted before deposition of the second layer 130_2.

After reaching stable flow conditions, the formation of the second layer 130_2, which comprises Si, N and H in a composition mentioned before, may be started by plasma ignition. The thickness of the second layer 130_2 depends on the flow rate of the process gases and the processing time in the processing chamber. For example, a relatively high gas flow of the gaseous Si compound between 500 sccm and 1200 sccm may be used. The flow of a gaseous N compound (e.g., N₂ and/or NH₃) may be set, e.g., between 3000 and 5000 sccm or even 8000 sccm, for example. The first layer 130_1 (specifically, the CusiN contained therein) allows the deposition of the second layer 130_2 having an over-stoichiometric Si content in a controllable way.

FIG. 6 is a flowchart illustrating exemplary stages of forming the passivation layer 130 over the metal structure 120 according to S3.

At S3_1 a CuSi layer 130_1a may be formed by thermal decomposition of a gaseous Si compound, in particular, silane. At this stage no plasma is ignited.

At S3_2 the CuSi layer 130_1a may be exposed to an N-containing plasma. As mentioned before, the N-containing plasma passivates (nitrides) the surface of the CuSi layer 130_1a by formation of the CusiN layer 130_1b to inhibit Si thermal decomposition thereon.

At S3_3 the first layer 130_1 (containing the CusiN layer 130_1b) may be exposed to a Si-containing and N-containing plasma. At that stage of the processing, the second layer 130_2 is formed.

The following examples pertain to further aspects of the disclosure:

Example 1 is a semiconductor device that includes a semiconductor substrate. A metal structure is disposed over the semiconductor substrate, wherein the metal of the metal structure is Cu or a Cu-based alloy. A passivation layer is disposed over the metal structure, wherein the passivation layer includes a first layer comprising CuSiN, and a second layer comprising Si, N and H, wherein, in atomic numbers, a ratio of Si to N is equal to or greater than 3.3/4.

In Example 2, the subject matter of Example 1 can optionally include wherein the ratio of Si to N is equal to or greater than 1.

In Example 3, the subject matter of Example 1 or 2 can optionally include wherein the second layer comprises 40 to 55 at % Si.

In Example 4, the subject matter of any preceding Example can optionally include wherein the second layer comprises 30 to 45 at % N.

In Example 5, the subject matter of any preceding Example can optionally include wherein the second layer comprises 12 to 17 at % H.

In Example 6, the subject matter of any preceding Example can optionally include wherein the first layer comprises a CuSiN layer having a thickness of 1 to 15 nm.

In Example 7, the subject matter of Example 6 can optionally include wherein the first layer further comprises a CuSi layer having a thickness of 0 to 200 nm, the CuSi layer being arranged below the CuSiN layer.

In Example 8, the subject matter of any preceding Example can optionally include wherein the second layer has a layer thickness of 40 to 500 nm.

In Example 9, the subject matter of any preceding Example can optionally include wherein the semiconductor device comprises an active region, a chip edge and an edge termination region separating the active region from the chip edge, the second layer extending over at least a portion of the edge termination region to proximate the chip edge or to the chip edge.

In Example 10, the subject matter of any preceding Example can optionally further include a third layer disposed between the first layer and the second layer, the third layer comprising aluminum oxide.

In Example 11, the subject matter of any preceding Example can optionally further include an imide layer disposed over the passivation layer.

In Example 12, the subject matter of any preceding Example can optionally include wherein the semiconductor device is a high voltage device.

In Example 13, the subject matter of any preceding Example can optionally include wherein the metal structure comprises one or more of a chip pad, a gate runner and/or a field plate of the semiconductor device.

In Example 14, the subject matter of any preceding Example can optionally include wherein the semiconductor device is a vertical device or a lateral device.

In Example 15, the subject matter of any preceding Example can optionally include wherein the semiconductor device is an IGBT, MOSFET, JFET, P-FET, N-FET, AFET, planar gate transistor, field plate trench transistor, or super junction transistor or diode.

Example 16 is a method of manufacturing a semiconductor device, the method comprising: providing a semiconductor substrate; forming a metal structure over the semiconductor substrate, wherein the metal of the metal structure is Cu or a Cu-based alloy; and forming a passivation layer over the metal structure, the forming of the passivation layer comprising: forming a first layer comprising CuSiN, and forming a second layer comprising Si, N and H, wherein, in atomic numbers, a ratio of Si to N is equal to or greater than 3.3/4.

In Example 17, the subject matter of Example 16 can optionally include wherein forming the first layer comprises: forming an initial CuSi layer; and exposing the CuSi layer to an N-containing plasma.

In Example 18, the subject matter of Example 16 or 17 can optionally include wherein the CuSi layer is formed by thermal decomposition of a gaseous Si compound, in particular silane.

In Example 19, the subject matter of any of Examples 16 to 18 can optionally include wherein forming the second layer comprises exposing the first layer to a Si-containing and N-containing plasma.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate;
a metal structure disposed over the semiconductor substrate, wherein a metal of the metal structure is Cu or a Cu-based alloy; and
a passivation layer disposed over the metal structure, wherein the passivation layer comprises:
a first layer comprising CuSiN; and
a second layer comprising Si, N and H, wherein, in atomic numbers, a ratio of Si to N is equal to or greater than 3.3/4.

2. The semiconductor device of claim 1, wherein the ratio of Si to N is equal to or greater than 1.

3. The semiconductor device of claim 1, wherein the second layer comprises 40 to 55 at % Si.

4. The semiconductor device of claim 1, wherein the second layer comprises 30 to 45 at % N.

5. The semiconductor device of claim 1, wherein the second layer comprises 12 to 17 at % H.

6. The semiconductor device of claim 1, wherein the first layer comprises a CuSiN layer having a thickness of 1 to 15 nm.

7. The semiconductor device of claim 6, wherein the first layer further comprises a CuSi layer having a thickness of 0 to 200 nm, the CuSi layer being arranged below the CuSiN layer.

8. The semiconductor device of claim 1, wherein the second layer has a layer thickness of 40 to 500 nm.

9. The semiconductor device of claim 1, further comprising:
an active region;
a chip edge; and
an edge termination region separating the active region from the chip edge,
wherein the second layer extends over at least a portion of the edge termination region to proximate the chip edge or to the chip edge.

10. The semiconductor device of claim 1, further comprising:
a third layer disposed between the first layer and the second layer, the third layer comprising aluminum oxide.

11. The semiconductor device of claim 1, further comprising:
an imide layer disposed over the passivation layer.

12. The semiconductor device of claim 1, wherein the semiconductor device is a high voltage device.

13. The semiconductor device of claim 1, wherein the metal structure comprises one or more of a chip pad, a gate runner, and/or a field plate of the semiconductor device.

14. The semiconductor device of claim 1, wherein the semiconductor device is a vertical device or a lateral device.

15. The semiconductor device of claim 1, wherein the semiconductor device is an IGBT, MOSFET, JFET, P-FET, N-FET, AFET, planar gate transistor, field plate trench transistor, or super junction transistor, or a diode.

16. A method of manufacturing a semiconductor device, the method comprising:
providing a semiconductor substrate;
forming a metal structure over the semiconductor substrate, wherein a metal of the metal structure is Cu or a Cu-based alloy; and
forming a passivation layer over the metal structure, the forming of the passivation layer comprising:
forming a first layer comprising CuSiN; and
forming a second layer comprising Si, N and H, wherein, in atomic numbers, a ratio of Si to N is equal to or greater than 3.3/4.

17. The method of claim 16, wherein forming the first layer comprises:
forming an initial CuSi layer; and
exposing the initial CuSi layer to an N-containing plasma.

18. The method of claim 17, wherein the initial CuSi layer is formed by thermal decomposition of a gaseous Si compound.

19. The method of claim 16, wherein forming the second layer comprises:
exposing the first layer to a Si-containing and N-containing plasma.
